(19) United States
(12) Patent Application Publication
(10) Pub. No.: US 2026/0056156 A1
(43) Pub. Date: Feb. 26, 2026

(54) PROCESS CHAMBER CONDUCTIVE FILM BUILD-UP DETECTOR

(71) Applicant: Applied Materials, Inc., Santa Clara, CA (US)

(72) Inventors: Edward P. HAMMOND, IV, Hillsborough, CA (US); Abhijit KANGUDE, Fremont, CA (US); Thomas RUBIO, Santa Clara, CA (US); Alexander GARACHTCHENKO, Santa Clara, CA (US)

(21) Appl. No.: 19/254,799

(22) Filed: Jun. 30, 2025

Related U.S. Application Data
(60) Provisional application No. 63/686,633, filed on Aug. 23, 2024.

(51) Int. Cl. G01N 27/22; G01N 27/02

(52) U.S. Cl. CPC G01N 27/228; G01N 27/028

(57) ABSTRACT

A processing chamber, including a processing volume, an interior surface, a sensor, and a control system. The interior surface is in fluid communication with the processing volume. The sensor is coupled to the interior surface and includes an electrode communicatively coupled to the control system. The control system is configured to supply a signal to the electrode and determine, based on the signal, at least one of a capacitance or an impedance of the interior surface of the processing chamber.

### CROSS-REFERENCE TO RELATED APPLICATION

This application claims priority to and the benefit of U.S. Provisional Ser. No. 63/686,633 , filed Aug. 23, 2024, which is incorporated by reference herein in its entirety.

### BACKGROUND

### Field

Embodiments of the present disclosure generally relate to a processing chamber for processing a substrate.

### Description of the Related Art

In the processing of substrates, such as semiconducting substrates, the substrate is placed on a support in a processing chamber and suitable processing conditions are maintained in the processing chamber. For example, the substrate can be placed in a processing chamber in preparation for a deposition process.

During deposition processes, residue, such as a conductive film, may be deposited in the processing chamber, such as on the interior surfaces and components of the processing chamber. For example, residue may be deposited on the walls of the processing chamber and downstream of the processing volume in a foreline.

Occasionally, the processing chamber is taken offline for cleaning to remove residue. The cleaning processes can be time-consuming thus reducing throughput of the processing chamber. Reducing the amount of time needed to claim the process chamber minimizes unnecessary downtime of the processing chambers. However, it can be difficult to predict when cleaning is required.

Accordingly, there is a need for an improved methods and apparatus to facilitate chamber cleaning.

### SUMMARY

In one embodiment, a processing chamber, including a processing volume, an interior surface, a sensor, and a control system. The interior surface is in fluid communication with the processing volume. The sensor is coupled to the interior surface and includes an electrode communicatively coupled to the control system. The control system is configured to supply a signal to the electrode and determine, based on the signal, at least one of a capacitance or an impedance of the interior surface of the processing chamber.

In another embodiment, a processing chamber, including a processing volume, an interior surface, a sensor, and a control system. The interior surface is in fluid communication with the processing volume. The sensor is coupled to the interior surface and includes a first electrode and a second electrode. The first electrode and second electrode are communicatively coupled to the control system. The control system is configured to supply a signal to the first electrode and determine, based on the signal, at least one of a capacitance or an impedance of the second electrode.

In yet another embodiment, a method of monitoring a conductive film in a processing chamber, including: supplying a signal to a first electrode disposed in an insert coupled to an interior surface of the processing chamber, determining a capacitance or an impedance between the first electrode and ground or between the first electrode and a second electrode, and detecting a conductive film deposited on the interior surface of the processing chamber based on the capacitance or the impedance.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 schematically illustrates a processing chamber, according to one or more embodiments.

FIG. 2 schematically illustrates the foreline of the processing chamber of FIG. 1 including a sensor, according to one or more embodiments.

FIG. 3 schematically illustrates the foreline of the processing chamber of FIG. 1 including another sensor, according to one or more embodiments.

FIG. 4 illustrates a method for monitoring a conductive film in a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a processing chamber. More specifically, embodiments described herein relate to a processing chamber sensor for detecting conductive film deposited within the processing chamber and foreline and methods for determining an amount of conductive film residue within the processing chamber and foreline.

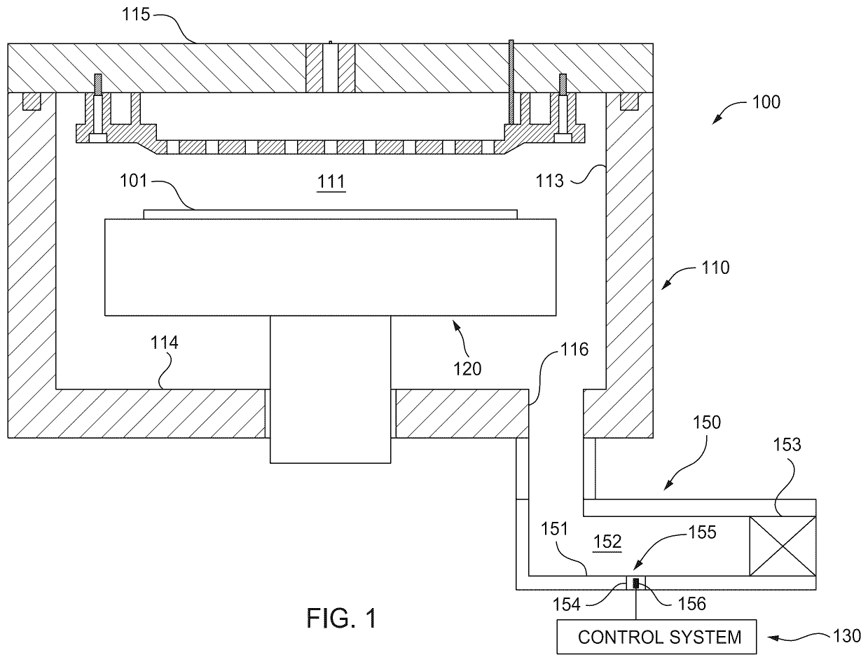

FIG. 1 schematically illustrates an exemplary processing chamber 100 for conducting a deposition process with a substrate 101. The processing chamber 100 includes a chamber body 110, a substrate support assembly 120, a control system 130, and a foreline 150.

The chamber body 110 includes a processing volume 111 at least partially defined by walls 113, a bottom 114, and a lid 115. The walls 113 and bottom 114 may be fabricated from a unitary block of aluminum. The chamber body 110 further includes an exhaust port 116 that fluidly couples the processing volume 111 to the foreline 150. Gases may flow from the processing volume 111 out of the chamber body 110 through the exhaust port 116 and into the foreline 150. For instance, the processing volume 111 and foreline 150 are in fluid communication. A pump (not shown) may be used to flow such gases.

The substrate support assembly 120 is disposed in the processing volume 111. The substrate support assembly 120 supports the substrate 101 during a deposition process. The substrate support assembly 120 generally is fabricated from aluminum, ceramic or a combination of aluminum and ceramic.

The foreline 150 is fluidly coupled to the processing volume 111 by the exhaust port 116. The foreline 150 is configured to direct flow out of the processing volume 111. The foreline 150 includes walls 151 that define the foreline volume 152. The foreline 150 may further include a throttle valve 153 disposed in the foreline volume 152.

The processing chamber 100 further includes a sensor 155 that is capacitance and/or resonance based. The sensor 155 is used to detect and monitor a conductive film that is deposited on the interior surfaces of the foreline 150 and/or one or more other surfaces of the processing chamber 100 during substrate deposition processes.

In various embodiments, the sensor includes an insert 154 and one or more electrodes 156. The insert 154 is made of an electrically isolating material, such as ceramic. In one or more embodiments, the insert 154 is made of aluminum oxide due to its strength and chemical compatibility. The insert 154 is disposed in an interior surface of the processing chamber 100 such that the insert 154 is fluidly exposed to the processing volume 111 (e.g., is in fluid communication with the processing volume 111) and defines a portion of the interior surface of the processing chamber 100. In one or more embodiments, the insert 154 is disposed in an interior surface of the processing chamber 100 at least partially defining the processing volume 111. In one or more embodiments, such as the one illustrated, the insert 154 is disposed in or on an interior surface of the foreline 150 upstream or downstream of the throttle valve 153. In one or more embodiments, the insert 154 may be disposed in a recess of an interior surface of the processing chamber 100. In one or more embodiments, the insert 154 forms a continuous surface with adjacent portions of the interior surface of the processing chamber 100. In one or more embodiments, the insert 154 is a ring and is installed into a circumferential recess within an interior surface of the processing chamber 100.

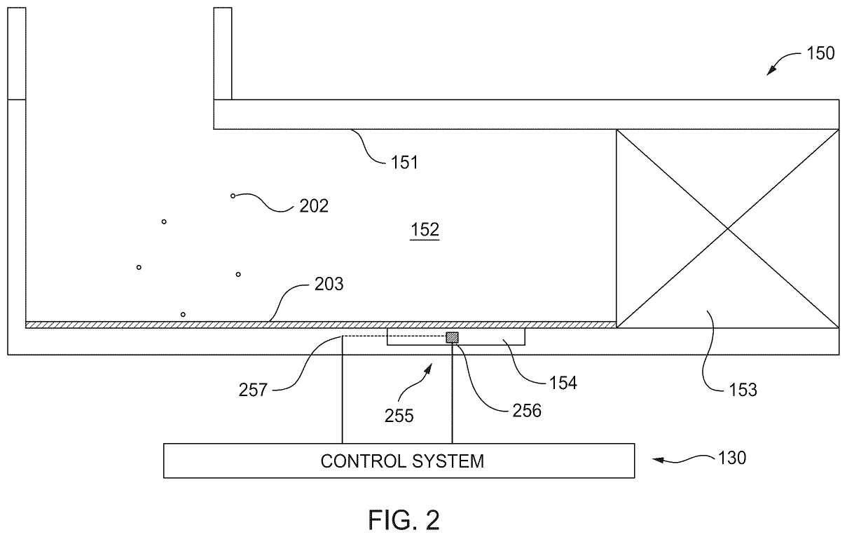

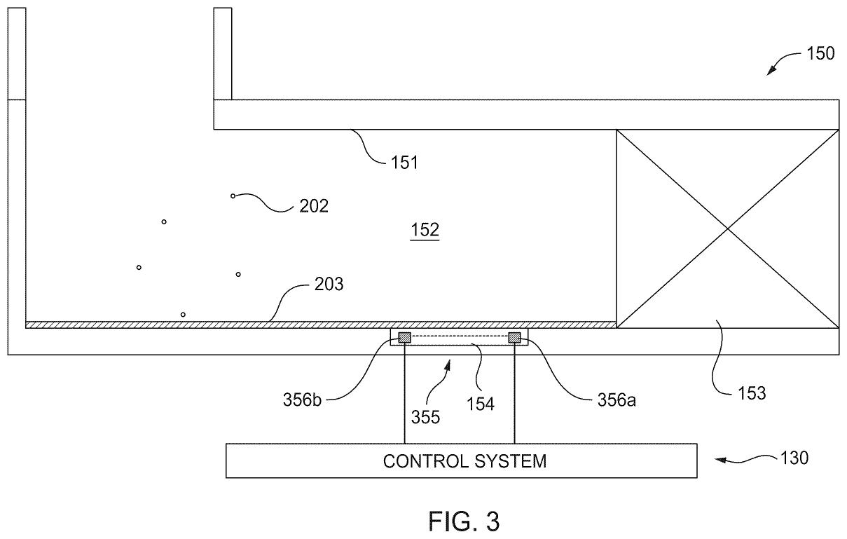

The one or more electrodes 156 are embedded in the insert 154. As an example, the sensor 155 may include one electrode 156 (as shown in FIG. 2). As another example, the sensor 155 may include two or more electrodes 156 (as shown in FIG. 3).

The control system 130 is communicatively coupled to the sensor 155 and, in some embodiments, may be coupled to ground (e.g., an interior surface of the processing chamber 100 not including the insert 154). The control system 130 is configured to monitor impedance and/or capacitive coupling between an electrode and either ground or the other electrode.

FIG. 2 schematically illustrates the foreline 150 with a sensor 255 having one electrode 256. The electrode 256 is embedded in the insert 154. The control system 130 is communicatively coupled to the electrode 256 at one end and is grounded to another portion of the processing chamber 100 not including the insert 154 (e.g., ground 257). In the illustrated embodiment, the electrode 256 is referenced to the wall 151 of the foreline 150 not including the insert 154. In some embodiments, the control system 130 supplies the electrode 256 with a low frequency signal. In one or more embodiments, the low frequency signal may be about 1 kilohertz (kHz) to about 1 megahertz (MHz). In one or more embodiments, the power level may be less than 1 watt (W). The control system 130 is also configured to measure and monitor the capacitive coupling and/or impedance between the electrode 256 and ground 257.

During a deposition process, a conductive material 202, such as carbon, may be deposited on the interior surfaces of the processing chamber 100 (e.g., the walls 113 and bottom 114 of the chamber body 110, the substrate support assembly 120, and the foreline 150). The deposited conductive material 202 creates a film 203 of conductive material 202 on the interior surfaces of the processing chamber 100. The film 203 may affect operation of the processing chamber 100. For instance, the film 203 may reduce conductance of the foreline 150 and/or the conductance of the throttle valve 153 thus changing the pumping characteristics of the processing chamber 100 and affecting the operation of the throttle valve 153. Thus, when the film 203 has accumulated, the processing chamber 100 is taken offline for cleaning. However, when the chamber 100 is taken offline, throughput of the processing chamber 100 is reduced. Accordingly, the sensor 255 and the control system 130 are used to monitor the accumulation of the film 203 to appropriately time cleaning of the processing chamber 100, improving chamber runtime.

The sensor 255 and control system 130 monitor and detect the accumulation of the film 203 by monitoring a capacitive coupling and/or impedance between the electrode 256 and the ground 257.

When the film 203 accumulates between the electrode 256 and the ground 257 (e.g., on the walls 151 of the foreline 150), the film 203 increases capacitive coupling between the electrode 256 and the ground 257 (e.g., the capacitive coupling of the interior surface). For instance, before the film 203 accumulates, a baseline value may be acquired for the capacitive coupling between the electrode 256 and the ground 257, the baseline value being indicative of at least a portion of the interior surfaces of the processing chamber 100 being clean or including less than a threshold level of film 203. After the film 203 has accumulated, the capacitive coupling may be at a higher level than the baseline value. The control system 130 measures and monitors this capacitive coupling between the electrode 256 and the ground 257.

In one or more embodiments, when the film 203 accumulates between the electrode 256 and the ground 257, the film 203 decreases impedance between the electrode 256 and the ground 257 (e.g., the impedance of the interior surface). For instance, before the film 203 accumulates, a baseline value may be acquired for the impedance between the electrode 256 and the ground 257, the baseline value being indicative of at least a portion of the interior surfaces of the processing chamber 100 being clean or including less than a threshold level of film 203. After the film 203 has accumulated, the impedance may be at a lower level than the baseline value. Accordingly, the control system 130 measures and monitors this impedance between the electrode 256 and the ground 257.

In one or more embodiments, when the film 203 accumulates between the electrode 256 and the ground 257, the film 203 increases capacitive coupling between the electrode 256 and the ground 257 (e.g., the capacitive coupling of the interior surface). For instance, before the film 203 accumulates, a baseline value may be acquired for the capacitive coupling between the electrode 256 and the ground 257, the baseline value being indicative of at least a portion of the interior surfaces of the processing chamber 100 being clean or including less than a threshold level of film 203. After the film 203 has accumulated, the capacitive coupling may be at a higher level than the baseline value. Accordingly, the control system 130 measures and monitors this impedance between the electrode 256 and the ground 257.

The control system 130 can use the capacitance and/or impedance measurements to determine whether the film 203 has accumulated on the interior surfaces of the processing chamber 100. Thus, through use of the sensor 255, the control system 130 may determine that the film 203 has accumulated thus indicating that the processing chamber 100 should be cleaned.

As the processing chamber 100 is cleaned, at least a portion of the film 203 is removed and the capacitive coupling between the electrode 256 and ground 257 is decreased. Similarly, as the processing chamber 100 is cleaned, at least a portion of the film 203 is removed and the impedance between the electrode 256 and ground 257 is increased. During cleaning, the control system 130 may measure and monitor the capacitive coupling and/or impedance between the electrode 256 and the ground 257 to determine that the processing chamber 100 has been sufficiently cleaned to be brought back online for further processing. In some embodiments, the processing chamber 100 is sufficiently clean when the capacitive coupling and/or impedance returns to the baseline value indicative of the interior surfaces of the processing chamber 100 being clean or an acceptable level of clean. In such embodiments, when the control system 130 determines that the measured capacitive coupling and/or impedance has reached the baseline value, the processing chamber 100 is deemed sufficiently cleaned and is brought back online for further processing.

FIG. 3 schematically illustrates the foreline 150 with a sensor 355 having two electrodes 356a, 356b. The two electrodes 356a, 356b are embedded in the insert 154. The two electrodes 356a, 356b are spaced apart within the insert 154. In one or more embodiments, the two electrodes 356a, 356b may be spaced apart about 1.0 mm to about 10.0 mm. In some embodiments, the control system 130 supplies one of the two electrodes 356a and 356b with a low frequency signal. The control system 130 is also configured to measure and monitor the capacitive coupling and/or impedance between the electrodes 356a and 356b.

During a deposition process, a conductive material 202, such as carbon, may be deposited on the interior surfaces of the processing chamber 100 (e.g., the walls 113 and bottom 114 of the chamber body 110, the substrate support assembly 120, and the foreline 150). The deposited conductive material 202 creates a film 203 of conductive material 202 on the interior surfaces of the processing chamber 100. The film 203 may affect operation of the processing chamber 100. For instance, the film 203 may reduce conductance of the foreline 150 and/or the throttle valve 153 changing the pumping characteristics of the processing chamber 100 and affecting the operation of the throttle valve 153. Thus, when the film 203 has accumulated, the processing chamber 100 should be taken offline for cleaning. However, when the chamber 100 is taken offline, throughput of the processing chamber 100 is reduced. Accordingly, the sensor 355 and the control system 130 are used to monitor the accumulation of the film 203 to appropriately time a cleaning of the processing chamber 100.

The sensor 355 and control system 130 monitor and detect the accumulation of the film 203 by monitoring a capacitive coupling and/or impedance between the two electrodes 356a, 356b.

When the film 203 accumulates between the electrodes 356a, 356b, the film 203 increases capacitive coupling between the electrodes 356a and 356b. For instance, before the film 203 accumulate, a baseline value may be acquired for the capacitive coupling between the electrodes 356a and 356b, the baseline value being indicative of at least a portion of the interior surfaces of the processing chamber 100 being clean or including less than a threshold level of film 203. After the film 203 has accumulated, the capacitive coupling may be at a higher level than the baseline value. The control system 130 measures and monitors this capacitive coupling between the electrodes 356a and 356b.

In one or more embodiments, when the film 203 accumulates between the electrodes 356a, 356b, the film 203 decreases impedance between the electrodes 356a, 356b. For instance, before the film 203 accumulates, a baseline value may be acquired for the impedance between the electrodes 356a and 356b, the baseline value being indicative of at least a portion of the interior surfaces of the processing chamber 100 being clean or including less than a threshold level of film 203. After the film 203 has accumulated, the impedance may be at a lower level than the baseline value. Accordingly, the control system 130 measures and monitors this impedance between the electrode 256 and the ground 257.

In one or more embodiments, when the film 203 accumulates between the electrodes 356a, 356b, the film 203 increases capacitive coupling between the electrodes 356a, 356b. For instance, before the film 203 accumulates, a baseline value may be acquired for the capacitive coupling between the electrodes 356a and 356b, the baseline value being indicative of at least a portion of the interior surfaces of the processing chamber 100 being clean or including less than a threshold level of film 203. After the film 203 has accumulated, the capacitive coupling may be at a higher level than the baseline value. Accordingly, the control system 130 measures and monitors this capacitive coupling between the electrode 256 and the ground 257.

The control system 130 can use the capacitance and/or impedance measurements to determine whether the film 203 that has accumulated on the interior surfaces of the processing chamber 100. Thus, through use of the sensor 355, the control system 130 may determine when the film 203 has accumulated thus requiring the processing chamber 100 to be cleaned.

As the processing chamber 100 is cleaned, at least a portion of the film 203 is removed and the capacitive coupling between the electrodes 356a and 356b is decreased. Similarly, as the processing chamber 100 is cleaned, at least a portion of the film 203 is removed and the impedance between the electrodes 356a, 356b is increased. During cleaning, the control system 130 may measure and monitor the capacitive coupling and/or impedance between the electrodes 356a, 356b to determine that the processing chamber 100 has been sufficiently cleaned to be brought back online for further processing. In some embodiments, the processing chamber 100 is sufficiently clean when the capacitive coupling and/or impedance returns to the baseline value indicative of the interior surfaces of the processing chamber 100 being clean. In such embodiments, when the control system 130 determines that the measured capacitive coupling and/or impedance has reached the baseline value, the processing chamber 100 is deemed sufficiently cleaned and is brought back online for further processing.

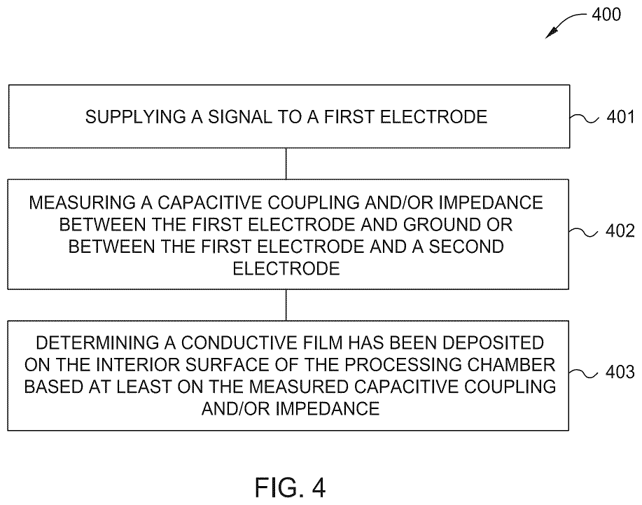

FIG. 4 illustrates a method 400 for monitoring a conductive film in a processing chamber. In one or more embodiments, a processing chamber (such as processing chamber 100 of FIG. 1) is initially configured. Configuring the processing chamber includes installing a sensor (such as sensors 155, 255, 355 of FIGS. 1-3) into a surface (e.g., an interior surface) of the processing chamber. For instance, the sensor may be at least partially disposed in a wall or bottom (such as wall 113 or bottom 114 of FIG. 1) of the processing chamber or a wall (such as wall 151 of FIGS. 1-3) of a foreline (such as foreline 150 of FIGS. 1-3). The sensor includes an insert (such as insert 154 of FIGS. 1-3) and one or more electrodes (such as electrodes 156, 256, 356a, and 356b of FIGS. 1-3) communicatively coupled to a control system (such as control system 130 of FIGS. 1-3). In some embodiments, the sensor includes one electrode at least partially disposed in the insert that is grounded to the interior surface of the processing chamber. In some embodiments, the sensor includes two electrodes at least partially disposed in the insert. In one or more embodiments, including two electrodes may make it easier to interleave the electrodes for enhanced sensitivity.

At activity 401, after the processing chamber has been configured, the control system supplies a low frequency signal to one of the one or more electrodes. In embodiments including one electrode, the low frequency signal is supplied to the one electrode. In embodiments including two electrodes, the low frequency signal is supplied to one of the two electrodes while the other remains grounded.

In one or more embodiments, the low frequency signal may be supplied to the electrode while the processing chamber is online and/or offline, that is, while the processing chamber is processing substrates (e.g., while conducting a deposition process) and/or while the processing chamber is not processing substrates.

At activity 402, the control system monitors and measures capacitive coupling and/or impedance. In embodiments including the one electrode, the control system monitors and measures the capacitive coupling and/or impedance between the electrode and ground (e.g., the interior surface of the processing chamber to which the electrode is grounded to). In embodiments including the two electrodes, the control system monitors and measures the capacitive coupling and/or impedance between the electrode that was supplied the low frequency signal and the other electrode.

In one or more embodiments, the capacitive coupling and/or impedance are being continuously monitored. For instance, the capacitive coupling and/or impedance may be monitored while the processing chamber is online and/or offline, that is, while the processing chamber is processing substrates (e.g., while conducting a deposition process) and/or while the processing chamber is not processing substrates.

At activity 403, based on the measurements taken by the control system at activity 402, the control system determines whether a conductive film (such as conductive film 203 of FIGS. 2-3) has accumulated and/or an amount of the conductive film that has accumulated on at least a portion of the interior surfaces of the processing chamber.

For instance, there may be a baseline capacitive coupling indicating that the interior surfaces of the processing chamber are clean (e.g., without a film). The conductive film deposited on the interior surfaces of the processing chamber increases the capacitive coupling between the electrode supplied with the signal and ground or the second electrode. Thus, as the capacitive coupling increases, the control system compares the measured capacitive coupling to the baseline capacitive coupling and determines a film is accumulating. Similarly, there may be a baseline impedance indicating that the interior surfaces of the processing chamber are clean (e.g., without a film). The conductive film deposited on the interior surfaces of the processing chamber may increase or decrease the impedance between the electrode supplied with the signal and ground or the second electrode. Thus, as the impedance decreases or increases, the control system compares the baseline impedance to the measured impedance and determines a film is accumulating.

Based on the determination made at activity 403, the control system may determine that the processing chamber should be taken offline to clean. While cleaning, the control system may continue monitoring and measuring the capacitive coupling and/or impedance between the electrode supplied with the signal and ground or the second electrode to determine if a predetermined level of cleaning is achieved. In some embodiments, once the control system determines that the interior surfaces of the processing chamber has been sufficiently cleaned, the processing chamber may be brought back online for further processing. In some embodiments, the determination that the interior surfaces processing chamber is sufficient clean includes determining that the capacitive coupling and/or impedance measured during cleaning has returned to the previously discussed baseline value.

Similarly, after determining that the interior surfaces of the processing chamber are sufficiently clean, the cleaning process may be stopped and the processing chamber may be brought back online for further processing of substrates.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a processing volume;
a foreline in fluid communication with the processing volume, the foreline including an interior surface;
a sensor coupled to the interior surface and comprising an electrode communicatively coupled to a control system; and
the control system is configured to:
supply a signal to the electrode; and
determine, based on the signal, at least one of a capacitance or an impedance of the interior surface of the foreline.

2. The processing chamber of claim 1, wherein:
the sensor further comprises an insert;
the electrode is disposed in the insert; and
the insert is disposed on the interior surface.

3. The processing chamber of claim 1, wherein the control system is configured to determine a capacitance of the interior surface of the foreline.

4. The processing chamber of claim 1, wherein the control system is configured to determine an impedance of the interior surface of the foreline.

5. The processing chamber of claim 1, wherein the control system is further configured to detect, based on the at least one of the capacitance or the impedance, a conductive film deposited on the interior surface of the foreline.

6. A processing chamber, comprising:
a processing volume;
a foreline in fluid communication with the processing volume, the foreline including an interior surface;
a sensor coupled to the interior surface and comprising a first electrode and a second electrode, wherein the first electrode and second electrode are communicatively coupled to a control system; and
the control system is configured to:
supply a signal to the first electrode; and
determine, based on the signal, at least one of a capacitance or an impedance between the first electrode and the second electrode.

7. The processing chamber of claim 6, wherein the control system is configured to determine the impedance between the first electrode and the second electrode.

8. The processing chamber of claim 6, wherein the sensor further comprises an insert, and wherein the insert is disposed on the interior surface.

9. The processing chamber of claim 8, wherein the first electrode and the second electrode are disposed in the insert.

10. The processing chamber of claim 6, wherein the interior surface comprises a processing chamber wall.

11. The processing chamber of claim 6, wherein the control system is further configured to detect, based on the at least one of the capacitance or the impedance, a conductive film deposited on the interior surface of the processing chamber.

12. A method of monitoring a conductive film in a processing chamber, comprising:
supplying a signal to a first electrode disposed in an insert coupled to an interior surface of a foreline of the processing chamber;
determining a capacitance or an impedance between the first electrode and ground or between the first electrode and a second electrode; and
detecting a conductive film deposited on the interior surface of the processing chamber based on the capacitance or the impedance.

13. The method of claim 12, wherein detecting the conductive film deposited on the interior surface of the processing chamber comprises:
comparing the capacitance or the impedance to a baseline value, wherein the baseline value is indicative of the interior surface of the processing chamber having less than a threshold amount of deposited conductive film; and
based on the comparing, detecting the conductive film deposited on the interior surface of the processing chamber.

14. The method of claim 13, wherein the capacitance being higher than the baseline value indicates the conductive film is deposited on the interior surface of the processing chamber.

15. The method of claim 13, wherein the impedance being lower than the baseline value indicates the conductive film is deposited on the interior surface of the processing chamber.

16. The method of claim 13, wherein the impedance being higher than the baseline value indicates the conductive film is deposited on the interior surface of the processing chamber.

17. The method of claim 12, wherein determining the capacitance or impedance between the first electrode and ground or between the first electrode and the second electrode comprises determining the capacitance or impedance between the first electrode and ground.

18. The method of claim 12, wherein determining the capacitance or impedance between the first electrode and ground or between the first electrode and the second electrode comprises determining the capacitance or impedance between the first electrode and the second electrode.

19. The method of claim 12, further comprising:
causing the processing chamber to be cleaned after detecting the conductive film deposited on the interior surface of the processing chamber;
determining a second capacitance or a second impedance between the first electrode and the ground or between the first electrode and the second electrode while the processing chamber is cleaned; and
determining the processing chamber having less than a threshold amount of deposited conductive film based on the second capacitance or the second impedance.

20. The method of claim 19, further comprising causing the cleaning to be stopped based on the determining the processing chamber has less than a threshold amount of deposited conductive film.
